(19) United States
(12) Patent Application Publication
(10) Pub. No.: US 2015/0357592 A1
(43) Pub. Date: Dec. 10, 2015

(54) ORGANIC LIGHT EMITTING DIODE DISPLAY

(71) Applicant: INNOLUX CORPORATION, Chu-Nan (TW)

(72) Inventors: Chun-Kai LI, Chu-Nan (TW); Yu-Hao LEE, Chu-Nan (TW); Hsin-Hui WU, Chu-Nan (TW)

(21) Appl. No.: 14/706,901

(22) Filed: May 7, 2015

(30) Foreign Application Priority Data
Jun. 10, 2014 (TW) 103120002

(51) Int. Cl. H01L 51/50; H01L 51/52

(52) U.S. Cl. CPC H01L 51/5012; H01L 51/5206; H01L 51/5221; H01L 51/5056; H01L 51/5072; H01L 51/5088; H01L 51/5092; H01L 2251/558

(57) ABSTRACT

An organic light emitting diode (OLED) display is provided. The OLED display includes a first electrode layer, a second electrode layer, a first light emitting layer, a second light emitting layer, a first n-type charge generation layer, a second n-type charge generation layer, and a metal layer. The first light emitting layer and the second light emitting layer are formed between the first electrode layer and the second electrode layer. The first n-type charge generation layer and the second n-type charge generation layer are formed between the first light emitting layer and the second light emitting layer. The metal layer is formed between the first n-type charge generation layer and the second n-type charge generation layer, wherein the metal layer has a first thickness.

This application claims the benefit of Taiwan application Serial No. 103120002, filed Jun. 10, 2014, the disclosure of which is incorporated by reference herein in its entirety.

### TECHNICAL FIELD

The disclosure relates in general to an organic light emitting diode (OLED) display, and more particularly to an OLED display having excellent display quality.

### BACKGROUND

Organic light emitting diode (OLED) display has the advantages of thinness, active lighting, not requiring backlight source, not having angle restriction. As the consumers expect high display quality of electronic products, the image resolution of the OLED display must be directed towards high resolution pixels and high display quality.

However, due to various process factors in the process of manufacturing light emitting elements of the OLED display, the display panel may still be subjected to problems such as color distribution being non-uniform, color purity being insufficient or luminous intensity being too low. Therefore, how to provide an OLED display having high display quality has become a prominent task to the industries.

### SUMMARY

The disclosure is directed to an organic light emitting diode (OLED) display. In an embodiment, through the adjustment in the design of the metal layer and in the relative distances between the metal layer and two light emitting layers, the luminescent properties of the OLED display can be adjusted.

According to one embodiment of the disclosure, an OLED display is provided. The OLED display comprises a first electrode layer, a second electrode layer, a first light emitting layer and a second light emitting layer, a first n-type charge generation layer, a second n-type charge generation layer and a first metal layer. The first light emitting layer and a second light emitting layer are formed between the first electrode layer and the second electrode layer. The first n-type charge generation layer and the second n-type charge generation layer are formed between the first light emitting layer and the second light emitting layer. The first metal layer is formed between the first n-type charge generation layer and the second n-type charge generation layer, wherein the first metal layer has a first thickness.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 is a schematic diagram of an OLED display according to an embodiment of the disclosure.

FIG. 2 is a schematic diagram of an OLED display according to another embodiment of the disclosure.

FIGS. 3A˜3B are relation diagrams of emission wavelength range vs. luminous intensity of an OLED display according to comparison example 1 and embodiment 1 of the disclosure.

FIG. 4 is a relation diagram of emission wavelength range vs. luminous intensity of an OLED display according to comparison example 2 and embodiment 2 of the disclosure.

FIGS. 5A˜5B are relation diagrams of emission wavelength range vs. luminous intensity of an OLED display according to comparison example 3 and embodiment 3 of the disclosure.

FIGS. 6A˜6B are relation diagrams of emission wavelength range vs. luminous intensity of an OLED display according to comparison example 4 and embodiment 4 of the disclosure.

### DETAILED DESCRIPTION

According to the embodiments of the disclosure, a metal layer is further added to the tandem OLED display such that the OLED display has two light emitting units. Therefore, the luminescent properties of the OLED display can be adjusted through the selection of material and thickness of the metal layer and the adjustment in the distance between the metal layer and two light emitting layers. Detailed descriptions of the embodiments of the disclosure are disclosed below with accompanying drawings. In the accompanying diagrams, the same numeric designations indicate the same or similar components. It should be noted that accompanying drawings are simplified so as to provide clear descriptions of the embodiments of the disclosure, and the following detailed description are exemplary and explanatory only and are not restrictive of the disclosed embodiments as claimed. Anyone who is skilled in the technology field of the disclosure can make necessary modifications or variations to the structures according to the needs in actual implementations.

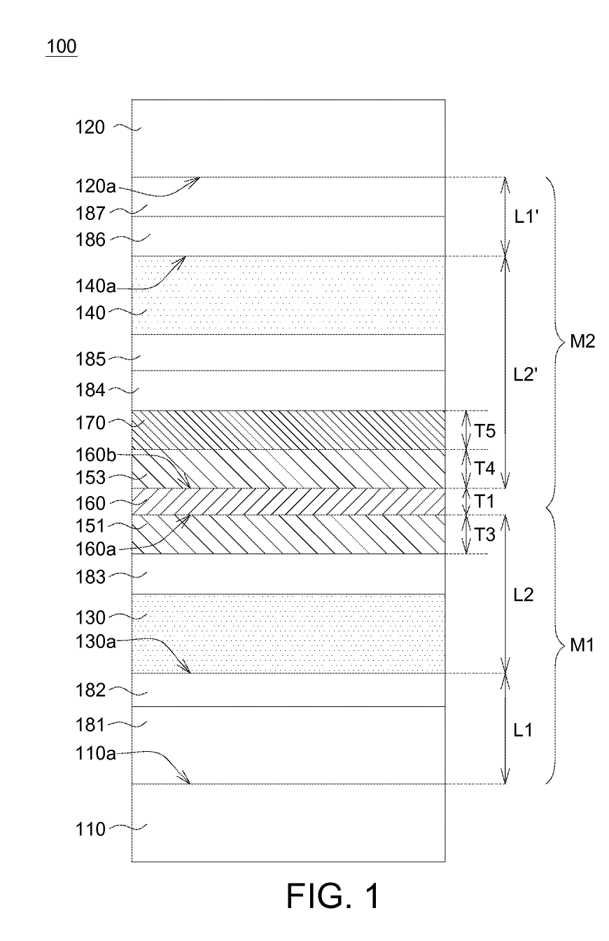

FIG. 1 is a schematic diagram of an OLED display 100 according to an embodiment of the disclosure. As indicated in FIG. 1, the OLED display 100 comprises a first electrode layer 110, a second electrode layer 120, a first light emitting layer 130, a second light emitting layer 140, a first n-type charge generation layers 151 and a second n-type charge generation layer 153 and a first metal layer 160. The first light emitting layer 130 and the second light emitting layer 140 are formed between the first electrode layer 110 and the second electrode layer 120. The first n-type charge generation layer 151 and the second n-type charge generation layer 153 are formed between the first light emitting layer 130 and the second light emitting layer 140. The first metal layer 160 is formed between the first n-type charge generation layer 151 and the second n-type charge generation layer 153, wherein the first metal layer 160 has a first thickness T1 which is greater than or equal to 10 nanometers (nm). The first n-type charge generation layer 151 and the second n-type charge generation layer 153 are formed from a low work function material doped with electron transport material, for example, formed from BPhen doped with lithium.

In the embodiment, the first thickness T1 of the first metal layer 160 is about 10˜150 nm, and can be formed from a refractive metal such as silver, aluminum or a combination thereof.

In the embodiment, the first electrode layer 110 is realized by an anode, and the second electrode layer 120 is realized by a cathode. In the embodiment, the first electrode layer 110 is realized by a reflective electrode layer or a transparent electrode layer, and the second electrode layer 120 is realized by a transparent electrode layer.

In an embodiment as indicated in FIG. 1, the OLED display 100 further comprises a p-type charge generation layer 170 formed between the second light emitting layer 140 and the second n-type charge generation layer 153. The p-type charge generation layer 170 can be formed from a strongly electron-pulling material (such as F4-TCNQ) doped with a hole transporting material, for example, formed from molybdenum trioxide (MoO₃).

As indicated in FIG. 1, the OLED display 100 can be regarded as having two light emitting units M1 and M2 separated by the first metal layer 160. The two light emitting units M1 and M2 can be connected by the p-type charge generation layer 170 and the n-type charge generation layers 151 and 153, such that the luminance can be doubled when the OLED display 100 is driven by a constant current. In other words, when the luminance provided by the OLED display 100 is fixed, the driving current of the OLED display 100 can be reduced, and the lifespan of the OLED display 100 can be prolonged. Besides, the first metal layer 160 makes the OLED display have two light emitting units M1 and M2, and the luminescent properties of the OLED display 100 can be adjusted through the selection of material and thickness of the first metal layer 160 and the adjustment in the distances between the first metal layer 160 and the first light emitting layer 130, the second light emitting layer 140, the first electrode layer 110 and the second electrode layer 120.

As indicated in FIG. 1, the first n-type charge generation layer 151 has a thickness T3, the second n-type charge generation layer 153 has a thickness T4, and the p-type charge generation layer 170 has a thickness T5. In the embodiment, the sum of the thickness T3 and the thickness T4 is about 10˜100 nm. In the present embodiment, the sum is exemplified by 10 nm. The thickness T5 is about 5˜100 nm, and is exemplified by 10 nm in the present embodiment.

In an embodiment, the ratio of the thickness T3 to the thickness T4 is 1:1˜1:10.

In an embodiment as indicated in FIG. 1, the OLED display 100 further comprises a first hole injection layer (HIL) 181, a first hole transport layer (HTL) 182 and a first electron transport layer (ETL) 183. The first hole injection layer 181 is formed on the first electrode layer 110, that is, between the first light emitting layer 130 and the first electrode layer 110. The first hole transport layer 182 is formed between the first light emitting layer 130 and the first hole injection layer 181. The first electron transport layer 183 is formed between the first n-type charge generation layer 151 and the first light emitting layer 130.

In an embodiment as indicated in FIG. 1, the OLED display 100 further comprises a second hole injection layer 184, a second hole transport layer 185, a second electron transport layer 186 and an electron injection layer 187. The second hole injection layer 184 is formed on the second n-type charge generation layer 153, that is, between the second light emitting layer 140 and the second n-type charge generation layer 153. The second hole transport layer 185 is formed between the second light emitting layer 140 and the second hole injection layer 184. The second electron transport layer 186 is formed on the second light emitting layer 140, that is, between the second light emitting layer 140 and the second electrode layer 120. The electron injection layer 187 is formed between the second electron transport layer 186 and the second electrode layer 120.

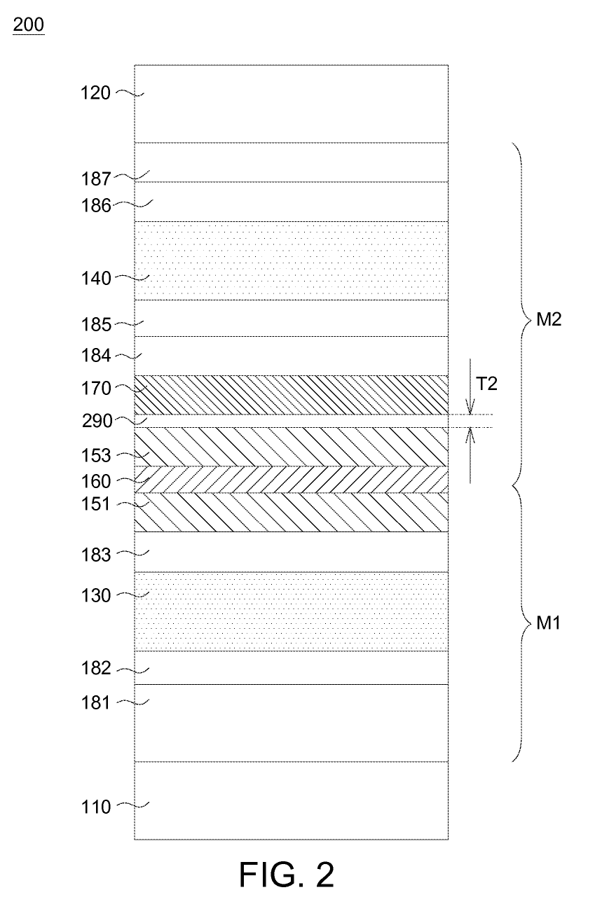

FIG. 2 is a schematic diagram of an OLED display 200 according to another embodiment of the disclosure. The elements common to the present embodiment and above embodiments retain the same numeric designations, and descriptions of common elements can be obtained with reference to above disclosure, and the similarities are not repeated here.

As indicated in FIG. 2, the OLED display 200 further comprises a second metal layer 290 formed between the p-type charge generation layer 170 and the second n-type charge generation layer 153. The second metal layer 290 has a second thickness T2 of such as less than or equal to 1 nm. The second metal layer 290 is realized by a metal having high conductivity capable of modifying the interface between the p-type charge generation layer 170 and the second n-type charge generation layer 153 to enhance charge generation, help the transport of electrons and holes, and increase the efficiency of charge generation.

Based on the Febry-Perot theory, micro cavities will be formed between two metal layers (such as two electrodes) of the OLED display, and the light will resonate in the micro cavities when the light source is disposed between the two metal layers. The two cavities respectively correspond to the two light emitting units M1 and M2. Light resonance affects luminous intensity, which is expressed as:

$${L}_{cav} ( λ , θ ) = {T}_{t} \frac{1 + {R}_{b} ( λ ) + 2 \sqrt{{R}_{b} ( λ )} cos ( 2 {kz}_{b} ( λ , θ ) )}{1 + {R}_{t} ( λ ) {R}_{b} ( λ ) - 2 \sqrt{{R}_{b} ( λ ) {R}_{t} ( λ )} cos ( 2 k {L}_{cav} ( λ , θ ) )} {I}_{0} ( λ )$$

Wherein, Rb represents the reflectivity of a metal layer at the bottom (a reflective electrode); zb represents a distance from the metal layer (the reflective electrode) to a light emitting position; Rt represents the reflectivity of a metal layer at the top (a semi-transparent electrode); k represents a wave vector; Lcav represents a cavity length; and Icav represents a luminous intensity.

Also, there are other parameters that affect the intensity and color of the output light. Apart from the reflectivity of the reflective electrode, the transmittance and absorption rate of the reflective electrode and the light emitting color of the light emitting layer also affect the intensity and color of the output light. Also, the light emitting surface of the light emitting layer can be regarded as the position of an anti-node, and constructive interference will be formed when the phase difference from the light emitting surface of the light emitting layer to the reflective electrode is an integral multiple of 2π.

In the embodiment, in the cavity of the light emitting unit M1, a light emitting surface 130a of the first light emitting layer 130 and a surface 110a of the first electrode layer 110 are separated by a first distance L1, and the light emitting surface 130a of the first light emitting layer 130 and a surface 160a of the first metal layer 160 are separated by a second distance L2. In the present embodiment, the first distance L1 is about 45˜65 nm or 140˜240 nm, and the second distance L2 is about 45˜65 nm or 140˜240 nm. Also, the values of L1 and L2 are not restricted as long as the sum of L1 and L2 satisfies the condition that constructive interference is formed when the phase difference from the light emitting surface of the light emitting layer to the reflective electrode is an integral multiple of 2π.

In the embodiment, in the cavity of the light emitting unit M2, a light emitting surface 140a of the second light emitting layer 140 and a surface 120a of the second electrode layer 120 are separated by a third distance L1′, the light emitting surface 140a of the second light emitting layer 140 and a surface 160b of the first metal layer 160 are separated by a fourth distance L2′, the third distance L1′ is about 55˜65 nm, and the fourth distance L2′ is about 55˜65 nm. The sum of L1′ and L2′ is the cavity length Lcav, and the values of L1′ and L2′ are not restricted as long as the sum of L1′ and L2′ satisfies the condition that constructive interference is formed when the phase difference from the light emitting surface 140a of the second light emitting layer 140 to the second electrode layer 120 and the first metal layer 160 is an integral multiple of 2π.

A number of embodiments are disclosed below for detailed descriptions of the disclosure. Refer to FIG. 1. In the embodiments and comparison examples disclosed below, the properties of some elements of the OLED display 100 are changed, and the luminous intensity and chromaticity coordinate of the OLED display in each embodiment and comparison example are measured. However, the embodiments below are for explanatory purpose, not for limiting the scope of protection of the disclosure.

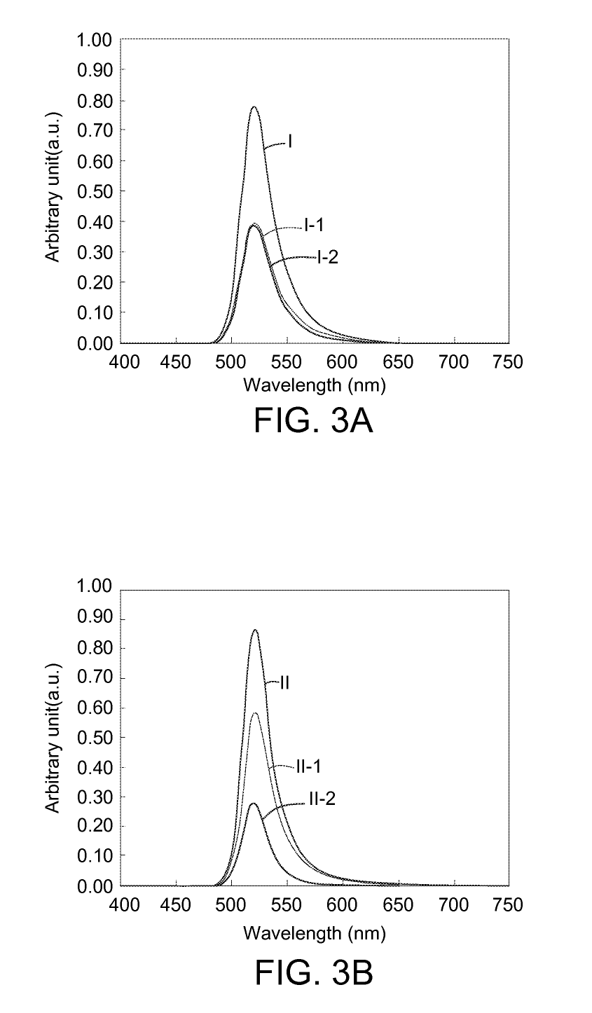

FIGS. 3A-3B are relation diagrams of emission wavelength range vs. luminous intensity of an OLED display according to comparison example 1 and embodiment 1 of the disclosure. Both the first light emitting layer 130 and the second light emitting layer 140 emit a green light (a monochromatic light), the first electrode layer 110 is realized by a reflective electrode layer, and the second electrode layer 120 is realized by a transparent electrode layer. Thus, the output light of the OLED display 100 is emitted from one side only and towards the direction of the cathode (the second electrode layer 120).

In embodiment 1, the thickness T1 of the first metal layer 160 is about 10˜40 nm, and preferably about 10˜30 nm.

FIGS. 3A˜3B and Table 1 illustrate the results obtained by measuring the OLED display 100 whose thicknesses T1, T3, T4, and T5 are 10 nm, 5 nm, 5 nm and 10 nm respectively, and distances L1, L2, L1′ and L2′ all are 55 nm. Both comparison example 1 and embodiment 1 have a p-type charge generation layer. Comparison example 1 does not have a first metal layer 160, but embodiment 1 has a first metal layer 160.

TABLE 1

| | Luminous | Chromaticity | Chromaticity |
|---|---|---|---|
| | Intensity | Coordinate | Coordinate |
| | (cd/m²) | (x) | (y) |
| Embodiment 1 | 113% | 0.198 | 0.725 |
| (FIG. 3B) | | | |
| Comparison | 100% | 0.207 | 0.716 |
| Example 1 | | | |
| (FIG. 3A) | | | |

In comparison example 1 as indicated in FIG. 3A, curve I-1 corresponds to the luminescent properties of the light emitting unit M1, curve I-2 corresponds to the luminescent properties of the light emitting unit M2, and curve I corresponds to the luminescent properties of the overall OLED display. In embodiment 1 as indicated in FIG. 3B, curve II-1 corresponds the luminescent properties of to the light emitting unit M1, curve II-2 corresponds to the luminescent properties of the light emitting unit M2, and curve II corresponds to the luminescent properties of the overall OLED display.

In comparison to comparison example 1, in embodiment 1 as indicated in FIG. 3B, the cavity resonance of the light emitting unit M1 is improved and the luminous intensity of the light emitting unit M1 is increased. Also, the curves I and II show that the luminous intensity of the overall OLED display is increased to 0.90 from 0.80. In embodiment 1 as indicated in Table 1, the x value of the chromaticity coordinate is reduces but the y value is increased, and such changes indicate that the purity of the green light is increased.

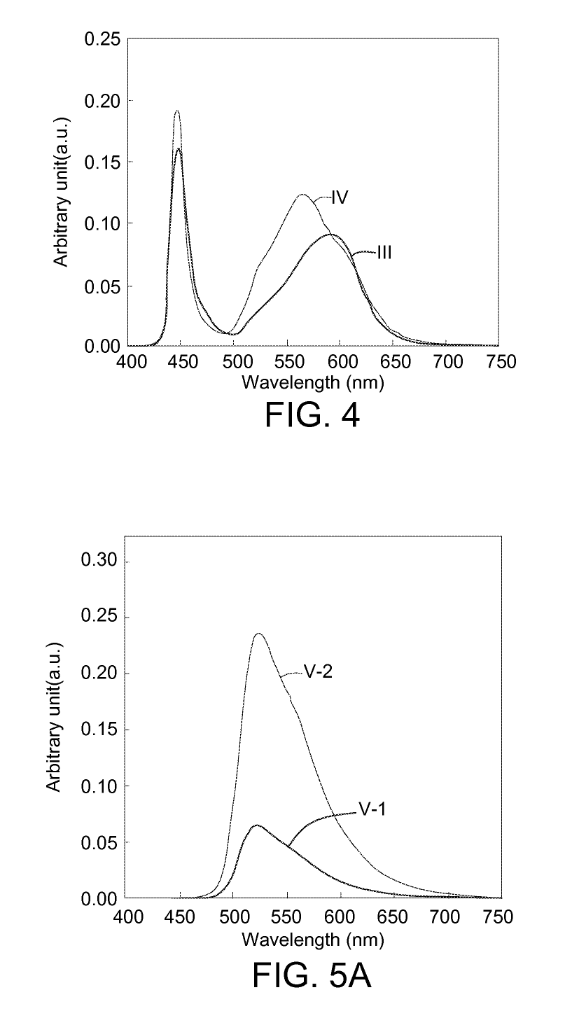

FIG. 4 is a relation diagram of emission wavelength range vs. luminous intensity of an OLED display according to comparison example 2 and embodiment 2 of the disclosure. The first light emitting layer 130 emits a blue light, the second light emitting layer 140 emits a yellow light, the first electrode layer 110 is realized by a reflective electrode layer, and the second electrode layer 120 is realized by a transparent electrode layer. Thus, the output light of the OLED display 100 is emitted from one side only, and the OLED display 100 further mixes the blue light and the yellow light to form a white light emitted towards the cathode (the second electrode layer 120).

In embodiment 2, the thickness T1 of the first metal layer 160 is about 10˜40 nm, and preferably about 10˜30 nm.

FIG. 4 and Table 2 illustrate the results obtained by measuring the OLED display 100 whose thicknesses T1, T3, T4, and T5 are 10 nm, 5 nm, 5 nm and 10 nm respectively, distances L1 and L2 both are 45 nm, and distances L1′ and L2′ both are 60 nm. Both comparison example 2 and embodiment 2 have a p-type charge generation layer. Comparison example 2 does not a first metal layer 160, but embodiment 2 has a first metal layer 160.

TABLE 2

| | Luminous | Chromaticity | Chromaticity |
|---|---|---|---|
| | Intensity | Coordinate | Coordinate |
| | (cd/m2) | (x) | (y) |
| Embodiment 2 | 146% | 0.348 | 0.372 |
| Comparison | 100% | 0.357 | 0.312 |
| example 2 | | | |

As indicated in FIG. 4, curve III corresponds to the luminescent properties of the OLED display of comparison example 2, and curve IV corresponds to the luminescent properties of the OLED display of embodiment 2.

In comparison to comparison example 2, in embodiment 2 as indicated in FIG. 4, the cavity resonance of the light emitting unit M1 emitting the blue light is improved, and the luminous intensity of the light emitting unit M1 is improved. Also, the cavity length of the light emitting unit M2 is reduced. Since the reduction in cavity length is conducive to the resonance of the yellow light, the cavity resonance of the light emitting unit M2 emitting the yellow light is improved, and the luminous intensity of the light emitting unit M2 is also increased. Also, as indicated in Table 2, the luminous intensity of embodiment 2 is increased to 146%, and the y value of the chromaticity coordinate is also increased. The increase in the y value of the chromaticity coordinate indicates that the emitted white light belongs to warm colors.

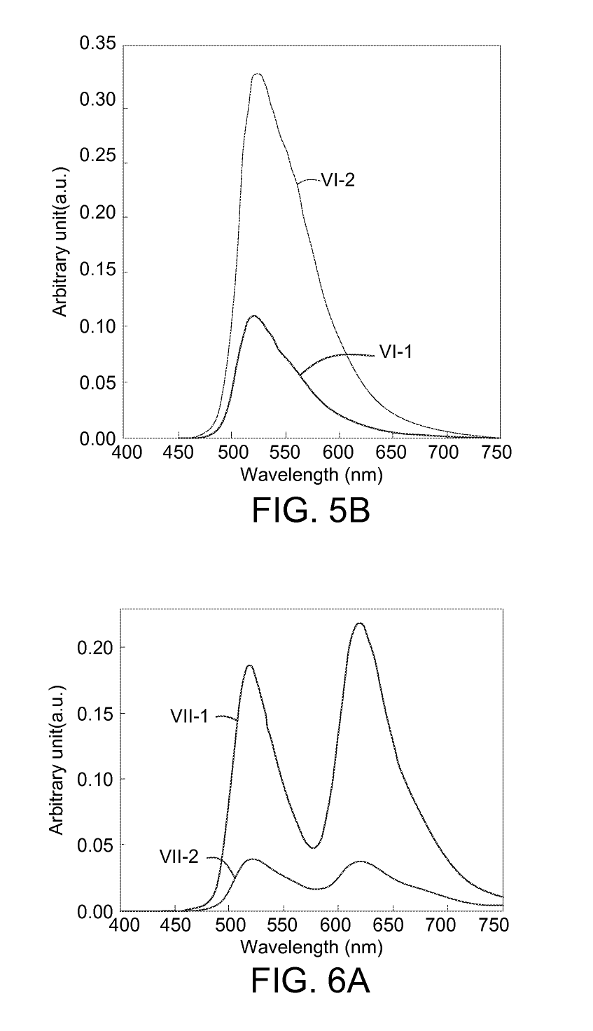

FIGS. 5A˜5B are relation diagrams of emission wavelength range vs. luminous intensity of an OLED display according to comparison example 3 and embodiment 3 of the disclosure. The first electrode layer 110 and the second electrode layer 120 can both be realized by a transparent electrode layer. Thus, the output light of the OLED display 100 can be emitted from two sides and towards the anode (the first electrode layer 110) and the cathode (the second electrode layer 120) respectively.

In embodiment 3, the thickness T1 of the first metal layer 160 is about 10˜150 nm.

FIGS. 5A˜5B and Table 3 illustrate the results obtained by measuring the OLED display 100 whose thicknesses T1, T3, T4, and T5 are 10 nm, 5 nm, 5 nm and 10 nm respectively, and distances L1, L2, L1′ and L2′ all are 55 nm. Both comparison example 3 and embodiment 3 have a p-type charge generation layer. Comparison example 3 does not have a first metal layer 160, but embodiment 3 has a first metal layer 160.

TABLE 3

| | Luminous | Chromaticity | Chromaticity |
|---|---|---|---|
| | Intensity | Coordinate | Coordinate |
| | (cd/m²) | (x) | (y) |
| Comparison Example 1 | 100% | 0.335 | 0.614 |
| (V-1 of FIG. 5A) | | | |
| Comparison Example 1 | 100% | 0.325 | 0.621 |
| (V-2 of FIG. 5A) | | | |
| Embodiment 1 | 140.92% | 0.334 | 0.617 |
| (VI-1 of FIG. 5B) | | | |
| Embodiment 1 | 156.65% | 0.304 | 0.634 |
| (VI-2 of FIG. 5B) | | | |

In comparison example 3 as indicated in FIG. 5A, curve V-1 corresponds to the luminescent properties of the light emitting unit M1 of the first electrode layer 110 (cathode), and curve V-2 corresponds to the luminescent properties of the light emitting unit M2 of the second electrode layer 120 (the anode). In embodiment 3 as indicated in FIG. 5B, curve VI-1 corresponds to the luminescent properties of the light emitting unit M1 of the first electrode layer 110 (the cathode), and curve VI-2 corresponds to the luminescent properties of the light emitting unit M2 of the second electrode layer 120 (the anode).

No structure in comparison example 3 comprises any reflective electrode or any reflective metal layer. In embodiment 3 as indicated in FIG. 5B embodiment 3, due to the disposition of the first metal layer 160, the cavity resonance of both the light emitting unit M1 and that of the light emitting unit M2 are enhanced, and the luminous intensities on both sides are increased. As indicated in Table 3, embodiment 3, the luminous intensities of both sides are largely increased.

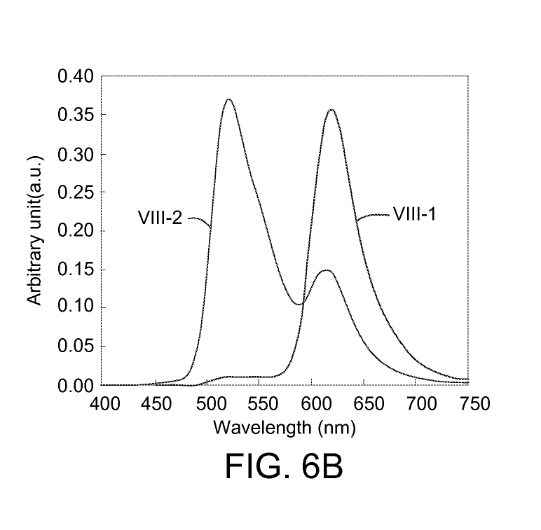

FIGS. 6A˜6B are relation diagrams of emission wavelength range vs. luminous intensity of an OLED display according to comparison example 4 and embodiment 4 of the disclosure. The first light emitting layer 130 emits a red light, the second light emitting layer 140 emits a green light, and the first electrode layer 110 and the second electrode layer 120 can both be realized by a transparent electrode layer. Thus, the output light of the OLED display 100 can be emitted from two sides and towards the anode (the first electrode layer 110) and the cathode (the second electrode layer 120). Since the first metal layer 160 of embodiment 4 is not transparent, the light emitted by the first light emitting layer 130 does not mix with the light emitted by the second light emitting layer 140.

In embodiment 4, the thickness T1 of the first metal layer 160 is about 10˜150 nm, and preferably about 30˜150 nm.

FIGS. 6A-6B illustrate the results obtained by measuring the OLED display 100 whose thicknesses T1, T3, T4, and T5 are 30 nm, 5 nm, 5 nm and 10 nm respectively, distances L1 and distance L2 are 65 nm and distances L1′ and L2′ both are 55 nm. Both comparison example 4 and embodiment 4 have a p-type charge generation layer. Comparison example 4 does not have a first metal layer 160, but embodiment 4 has a first metal layer 160.

In comparison example 4 as indicated in FIG. 6A, curve VII-1 corresponds to the luminescent properties of the light emitting unit M1 of the first electrode layer 110 (the anode), and curve VII-2 corresponds to the luminescent properties of the light emitting unit M2 of the second electrode layer 120 (the cathode). In embodiment 4 as indicated in FIG. 6B, curve VIII-1 corresponds to the luminescent properties of the light emitting unit M1 of the first electrode layer 110 (the anode), and curve VIII-2 corresponds to the luminescent properties of the light emitting unit M2 of the second electrode layer 120 (the cathode).

As indicated in FIG. 6A, no structure in comparison example 4 comprises any reflective electrode or any reflective metal layer. Since there are no obstacles existing between the red light emitted by the first fluorescent layer 130 and the green light emitted by the second fluorescent layer 140, the red light and the green light are mixed to form a yellow light. In embodiment 4 as indicated in FIG. 6B, due to the disposition of the first metal layer 160, both the cavity resonance of the light emitting unit M1 and the cavity resonance of the light emitting unit M2 are increased and the light inside one cavity is blocked and will not enter the other cavity. The OLED display 100 not only has enhanced luminous intensity on both sides but is also capable of displaying respective color light on the two sides. Therefore, the two screens can receive different information but still share the same body, and such design benefits the manufacturing of super-thin screen.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. An organic light emitting diode (OLED) display, comprising:
a first electrode layer and a second electrode layer;
a first light emitting layer and a second light emitting layer formed between the first electrode layer and the second electrode layer;
a first n-type charge generation layer and a second n-type charge generation layer formed between the first light emitting layer and the second light emitting layer; and
a first metal layer formed between the first n-type charge generation layer and the second n-type charge generation layer, wherein the first metal layer has a first thickness.

2. The OLED display according to claim 1, wherein the first thickness of the first metal layer is 10˜150 nm.

3. The OLED display according to claim 1, wherein the first thickness of the first metal layer is 10˜40 nm.

4. The OLED display according to claim 1, wherein the first metal layer comprises silver, aluminum or a combination thereof.

5. The OLED display according to claim 1, further comprising:
a p-type charge generation layer formed between the second light emitting layer and the second n-type charge generation layer; and
a second metal layer formed between the p-type charge generation layer and the second n-type charge generation layer, wherein the second metal layer has a second thickness.

6. The OLED display according to claim 5, wherein the first n-type charge generation layer has a third thickness, the second n-type charge generation layer has a fourth thickness, the p-type charge generation layer has a fifth thickness of 5˜100 nm, and a sum of the third thickness and the fourth thickness is 10˜100 nm.

7. The OLED display according to claim 1, wherein the first n-type charge generation layer has a third thickness, the second n-type charge generation layer has a fourth thickness, and a ratio of the third thickness to the fourth thickness is 1:1˜1:10.

8. The OLED display according to claim 1, wherein a light emitting surface of the first light emitting layer and a surface of the first electrode layer are separated by a first distance of 45˜65 nm or 140˜240 nm, and the light emitting surface of the first light emitting layer and a surface of the first metal layer are separated by a second distance of 45˜65 nm.

9. The OLED display according to claim 1, wherein a light emitting surface of the second light emitting layer and a surface of the second electrode layer are separated by a third distance of 55˜65 nm, and the light emitting surface of the second light emitting layer and a surface of the first metal layer are separated by a fourth distance of 55˜65 nm.

10. The OLED display according to claim 1, further comprising:
a first hole injection layer formed between the first electrode layer and the first light emitting layer;
a first hole transport layer formed between the first light emitting layer and the first hole injection layer;
a first electron transport layer formed between the first n-type charge generation layer and the first light emitting layer;
a second hole injection layer formed between the second n-type charge generation layer and the second light emitting layer;
a second hole transport layer formed between the second light emitting layer and the second hole injection layer;
a second electron transport layer formed between the second light emitting layer and the second electrode layer; and
an electron injection layer formed between the second electron transport layer and the second electrode layer.
